(19) United States
(12) Patent Application Publication
(10) Pub. No.: US 2026/0096175 A1
(43) Pub. Date: Apr. 2, 2026

(54) CFET POWER CONNECTION STRUCTURE AND THE METHODS OF FORMING THE SAME

(71) Applicant: Taiwan Semiconductor Manufacturing Co., Ltd., Hsinchu (TW)

(72) Inventors: Meng-Yu Lin, New Taipei (TW); Ping Huang, Hsinchu (TW); Chun-Fu Cheng, Zhubei (TW)

(21) Appl. No.: 19/021,706

(22) Filed: Jan. 15, 2025

Related U.S. Application Data
(60) Provisional application No. 63/699,946, filed on Sep. 27, 2024.

(51) Int. Cl. H10D 64/23; H01L 21/308; H10D 64/62; H10D 84/01; H10D 84/85

(52) U.S. Cl. CPC H10D 64/254; H10D 84/0186; H10D 84/851; H10P 50/691; H10D 64/62

(57) ABSTRACT

A method includes forming a complementary field-effect transistor comprising forming a lower source/drain region, and forming an upper source/drain region over the lower source/drain region. An etching process is performed to etch-through the upper source/drain region and to form a contact opening. The etching process is stopped on a top surface of the lower source/drain region. The method further includes forming a dielectric contact spacer in the contact opening, forming a first silicide layer over the lower source/drain region, forming a contact plug over and contacting the first silicide layer, and forming a second silicide layer underlying and contacting a bottom surface of the lower source/drain region.

### PRIORITY CLAIM AND CROSS-REFERENCE

This application claims the benefit of the following provisionally filed U.S. Patent application: Application No. 63/699,946, filed on Sep. 27, 2024, and entitled “CFET Connection Structure;” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 13 are views of intermediate stages in the formation of CFETs and contact plugs in accordance with some embodiments.

FIG. 14 illustrates a flow chart for forming CFETs and backside connection structures in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs), contact plugs connected to the CFETs, and the method of forming the same are provided. In accordance with some embodiments of the present disclosure, the contact plugs include power contact plugs for connecting power from one side (such as bottom side or top side) to the other side through source/drain regions. Accordingly, it is not needed to form power contact plugs (which may negatively occupy the chip areas that can otherwise be used for forming wide channels) aside of the source/drain regions. The channel widths and hence the speed of the CFETs are thus not negatively affected by the power contact plugs. A plurality of contact plugs that may be connected to some of the source/drain regions may be formed, and combined with the power contact plugs to generate different routing schemes.

It is appreciated that while Gate-All-Around (GAA) transistors (such as nanostructure-FETs) are discussed, the concept of the present disclosure can also be applied to the formation of backside contact formation of CFETs formed of other types of transistors such as planar transistors, Fin Field-Effect Transistors (FinFETs), and the like. Throughout the description, the terms “FET” and “transistor”are used interchangeably.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

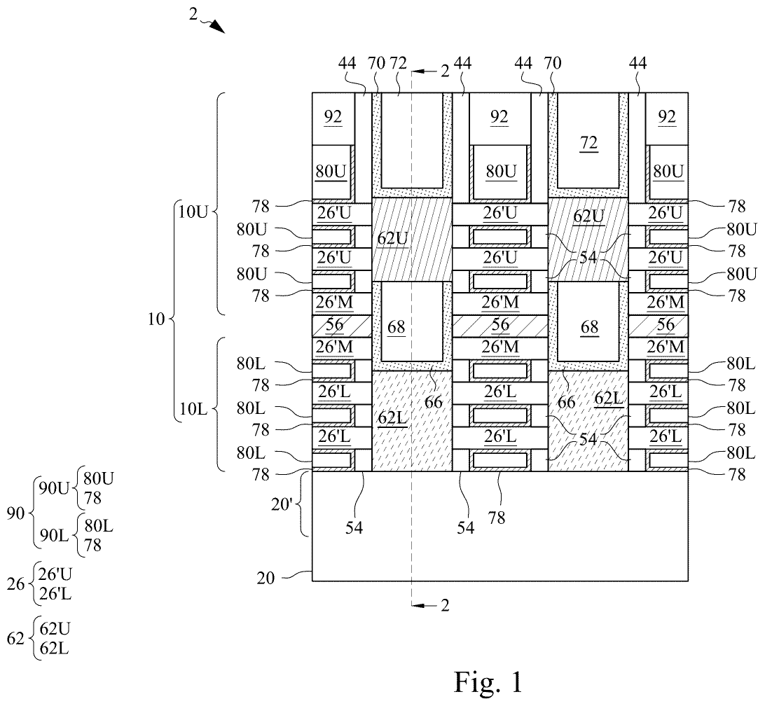

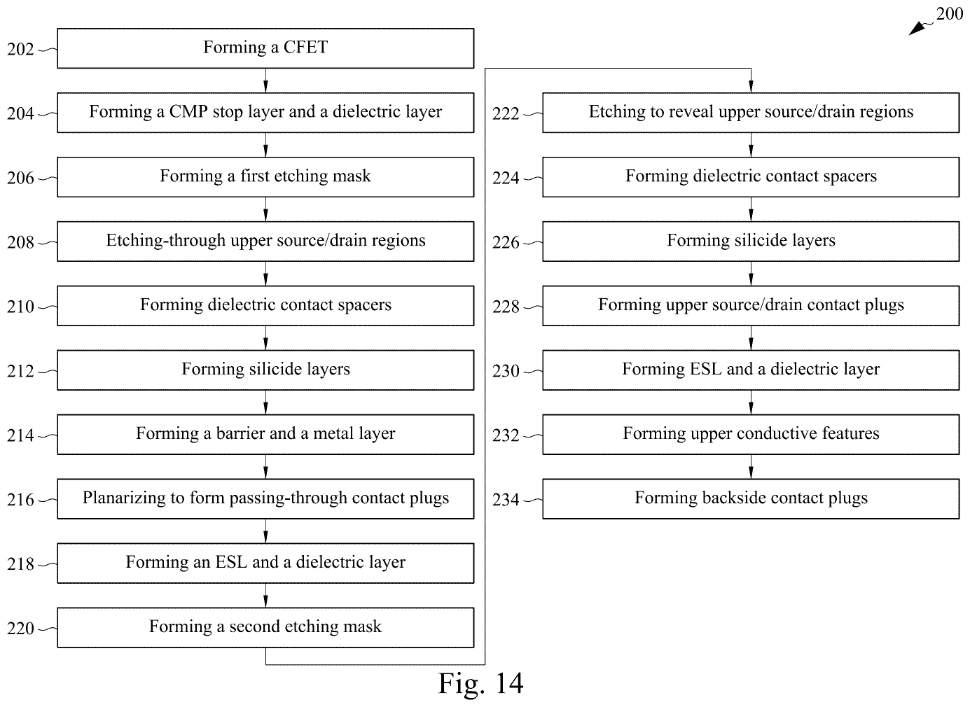

FIGS. 1 through 13 illustrate the cross-sectional views of intermediate stages in the formation of CFETs and contact plugs in accordance with some embodiments of the present disclosure. The corresponding processes are also reflected schematically in the process flow shown in FIG. 14.

FIG. 1 illustrates the formation of an example CFET 10 (including FETs (transistors) 10U and 10L) in accordance with some embodiments. The respective process is illustrated as process 202 in the process flow 200 as shown in FIG. 14. CFET 10 may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

As shown in FIG. 1, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

In the illustrated example, each of the upper FET 10U and lower FET 10L includes two semiconductor layers 26′U and 26′L, respectively, as the channels. It should be appreciated that the upper FET 10U and lower FET 10L may include any number of channel regions such as 1, 2, 3, or more. The portions of the gate stack 90 that are overlying and/or underlying the channel regions 26 form multilayer stacks with the corresponding channel regions 26′U and 26′L.

Gate stacks 90 (including upper gate stacks 90U and lower gate stacks 90L) are formed as including portions between semiconductor layers 26. Upper gate stacks 90U includes gate dielectrics 78 and upper gate electrodes 80U. Lower gate stacks 90L includes gate dielectrics 78 and lower gate electrodes 80L. Gate dielectrics 78 encircle (when viewed in side views) the respective semiconductor nanostructures 26. Gate electrodes 80 (including a lower gate electrode 80L and an upper gate electrode 80U) are over the gate dielectrics 78. Dielectric isolation layers 56 are formed to isolate the gate stack 90U of the upper FETs 10U from the gate stack 90L of the lower FETs 10L. Dummy semiconductor layers 26′M may be formed to contact dielectric isolation layers 56.

Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context.

Inner spacers 54, which are dielectric spacers, are formed on the opposing sides of the portions of gate stacks 90, which portions are between semiconductor layers 26. Inner spacers 54 electrically insulate the source/drain regions 62L and 62U from the corresponding parts of gate stacks 90 to prevent and reduce leakage.

Gate spacers 44 are formed over the multilayer stacks and on the sidewalls of gate stacks 90. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

Source/drain regions 62L and 62U are formed laterally between the multilayer stacks that comprise channel regions 26 and gate stacks 90. Lower source/drain regions 62L are formed over and contacting a substrate, which includes semiconductor substrate 20. The lower source/drain regions 62L are further in contact with the lower semiconductor nanostructures 26′L and are not in contact with the upper semiconductor nanostructures 26′U.

The lower source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants

A first contact etch stop layer (CESL) 66 and a first ILD 68 are formed over the lower source/drain regions 62L. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper source/drain regions 62U are formed through epitaxy. Upper source/drain regions 62U overlap the first CESL 66 and the first ILD 68, and overlap the lower source/drain regions 62L. The materials of lower source/drain regions 62U may be selected from the same candidate group of materials for forming lower source/drain regions 62L, depending on the desired conductivity type of lower source/drain regions 62U.

The conductivity type of the lower source/drain regions 62U may be opposite the conductivity type of the lower source/drain regions 62L. Alternatively stated, the lower source/drain regions 62U may be oppositely doped than the lower source/drain regions 62L. The lower source/drain regions 62U may be in-situ doped, and/or may be implanted, with an n-type or p-type dopant.

A second CESL 70 and a second ILD 72 are formed over the lower source/drain regions 62U. The materials may be similar to, and may be the same as or different from, the materials and the formation methods of the first CESL 66 and first ILD 68, respectively, and are not discussed in detail herein.

Gate masks 92 are formed over the gate stacks 90. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72. More dielectric layers (not illustrated) such as etch stop layers, inter-layer dielectric, inter-metal dielectric, or the like, may be formed over gate masks 92 and the second ILD 72.

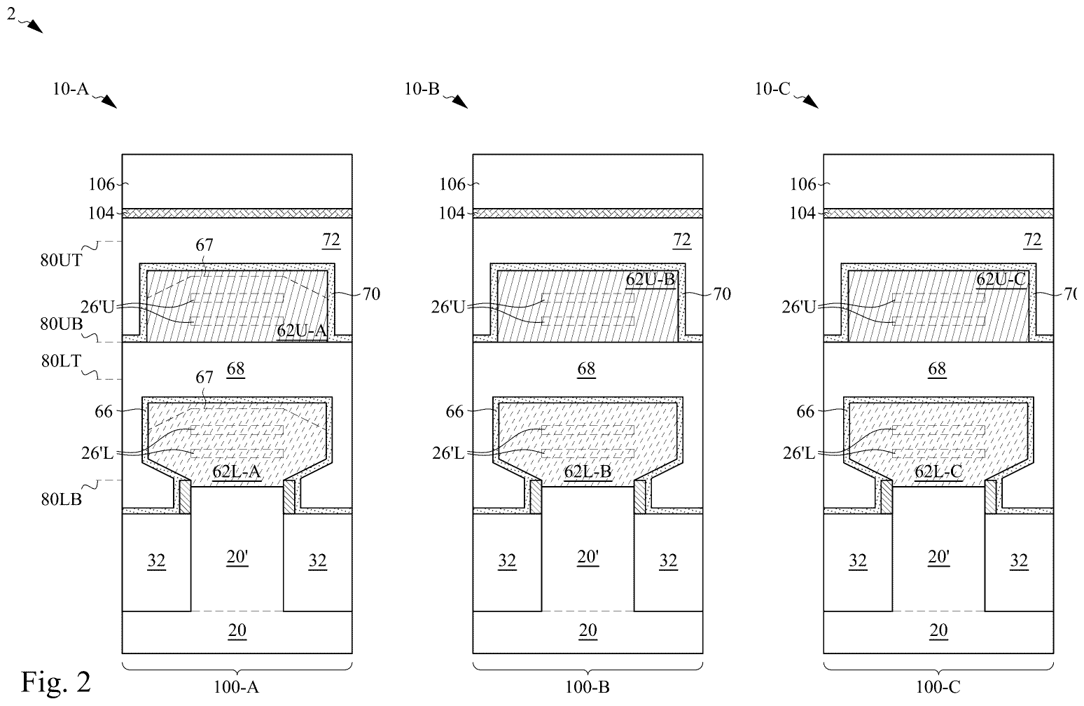

FIG. 2 illustrates the cross-sectional views of three CFETs 10-A, 10-B, and 10C, which are formed in device regions 100-A, 100-B, and 100-C, respectively, in accordance with some embodiments. Each of the CFETs 10-A, 10-B, and 10C may have essentially the same or similar structures as the CFET 10 as shown in FIG. 1, and hence their structures are not repeated. Throughout the description, some illustrated features may be denoted using the reference numbers followed by letter “A,” “B,” or “C” to represent that these features are the like features in device region 100-A, 100-B, or 100-C. For example, the lower source/drain regions 62L in device regions 100-A, 100-B, and 100-C are denoted as “62L-A,” “62L-B,” and “62L-C,” respectively. The upper source/drain regions 62U in device regions 100-A, 100-B, and 100-C are denoted as “62U-A,” “62U-B,” and “62U-C,” respectively.

Also, although the cross-sectional views of the top surfaces of lower source/drain regions 62L and upper source/drain regions 62U are illustrated as being planar, the top surfaces of these features may have other shapes such as having slanted facets, as shown by dashed lines 67, which are shown in device region 100-A as an example.

Dielectric isolation regions 32, also sometimes referred to as Shallow Trench Isolation (STI) regions 32, are formed over substrate 20. Semiconductor strips 20′ (also refer to FIG. 1) are formed between the STI regions 32. Fin spacers 45 may be formed on the sidewalls of the top portions of semiconductor strips 20′.

The illustrated cross-sections of CFETs 10-A, 10-B, and 10C may be the same as the cross-section 2-2 as shown in FIG. 1. Accordingly, the source/drain regions, CESLs, and ILDs are in the illustrated cross-sections in FIG. 2. Semiconductor layers 26′U and 26′L (FIG. 1), on the other hand, are not in the illustrated planes, and are thus illustrated as being dashed in FIG. 2. Dashed levels 80UT and 80UB are marked to represent the top surface level and the bottom surface level, respectively, of the upper gate electrode 80U, which are in the vertical cross-sections different than the illustrated vertical cross-sections. Dashed levels 80LT and 80LB are marked to indicate the top surface level and the bottom surface level, respectively, of the lower gate electrode 80L, which are also in the vertical cross-sections different than the illustrated vertical cross-sections.

Further referring to FIG. 2, Chemical Mechanical Polish (CMP) stop layer 104 and dielectric layer 106 are formed. The respective process is illustrated as process 204 in the process flow 200 as shown in FIG. 14. In accordance with some embodiments, CMP stop layer 104 may be formed of or comprise silicon nitride, and dielectric layer 106 may be formed of or comprise silicon oxide, while other applicable materials may be used. In accordance with alternative embodiments, dielectric layer 106 and CMP stop layer 104 are not formed.

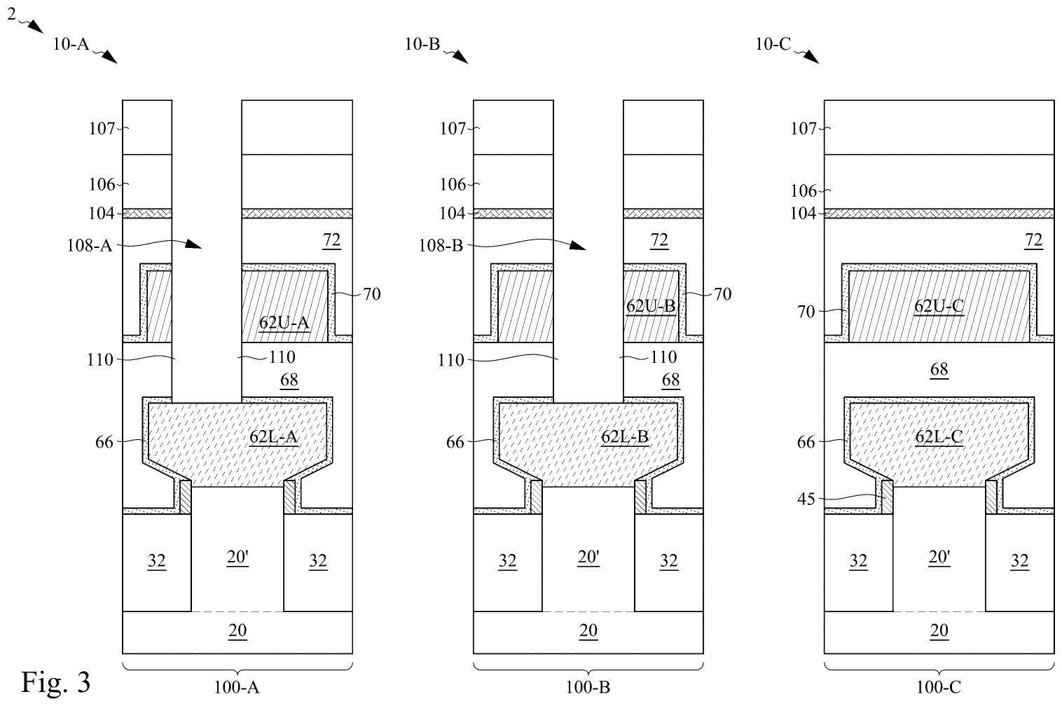

Referring to FIG. 3, a patterned etching mask 107, which may comprise, for example, a photoresist, is formed. The respective process is illustrated as process 206 in the process flow 200 as shown in FIG. 14.

An etching process is performed to etch dielectric layer 106, CMP stop layer 104, the second ILD 72 and the second CESL 70 in device regions 100-A and 100-B, and to form contact openings 108-A and 108-B, respectively. Contact openings 108-A and 108-B are thus formed through a same photolithography process using a same photolithography mask (not shown). The photolithography mask includes transparent portions allowing light to pass through and opaque portions for blocking light. Next, upper source/drain regions 62U-A and 62U-B are etched-through, so that contact openings 108-A and 108-B extend to the first ILD 68. The respective process is illustrated as process 208 in the process flow 200 as shown in FIG. 14.

In subsequent processes, the first ILD 68 and the first CESL 66 are further etched, so that lower source/drain regions 62L-A and 62L-B are exposed to contact openings 108-A and 108-B, respectively. Etching mask 107 is then removed.

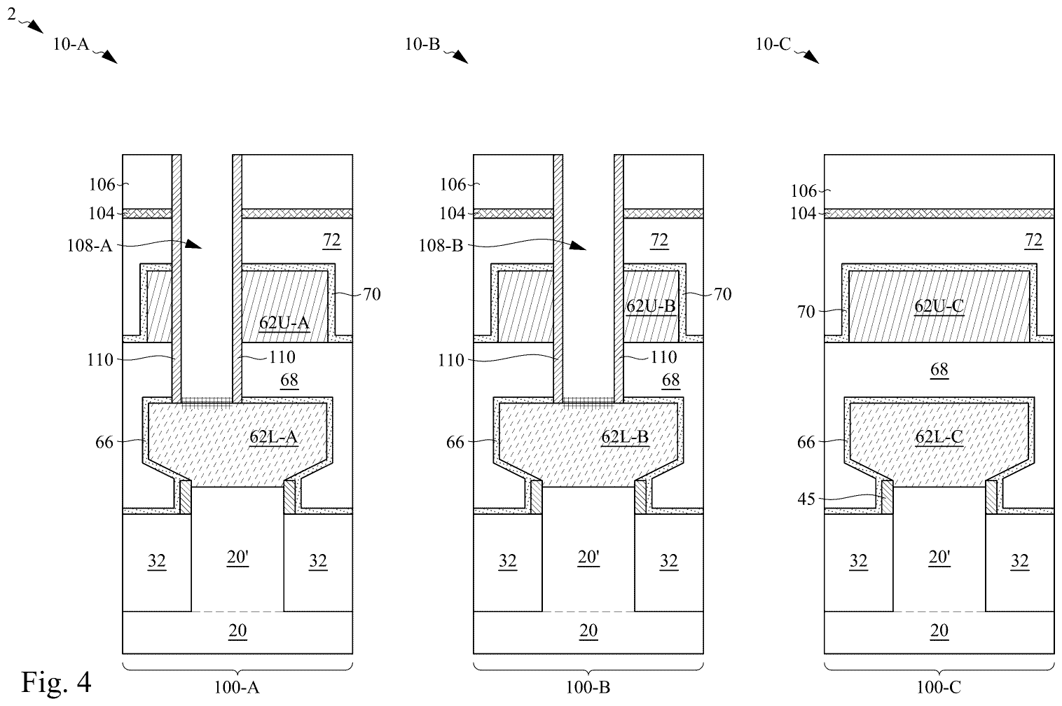

Referring to FIG. 4, dielectric contact spacers 110 are formed in contact openings 108-A and 108-B. The respective process is illustrated as process 210 in the process flow 200 as shown in FIG. 14. Dielectric contact spacers 110 are thus in contact with the sidewalls of the first CESL 66, the first ILD 68, the upper source/drain regions 62U-A and 62U-B, the second CESL 70, and the second ILD 72. In accordance with some embodiments, the formation of dielectric contact spacers 110 includes a conformal deposition process such as CVD or ALD to form a conformal dielectric layer. The conformal dielectric layer thus includes portions on top of the lower source/drain regions 62L-A and 62L-B, the portions over the top of the second ILD 72, and the portions on the illustrate sidewalls.

After the deposition of the conformal dielectric layer, an anisotropic etching process is performed, so that the horizontal portions of the conformal dielectric layer are removed, and the vertical portions of the dielectric conformal layer inside contact openings 108-A and 108-B are left to form dielectric contact spacers 110. Dielectric contact spacers 110 may form rings encircling contact openings 108-A and 108-B when viewed from the top of wafer 2.

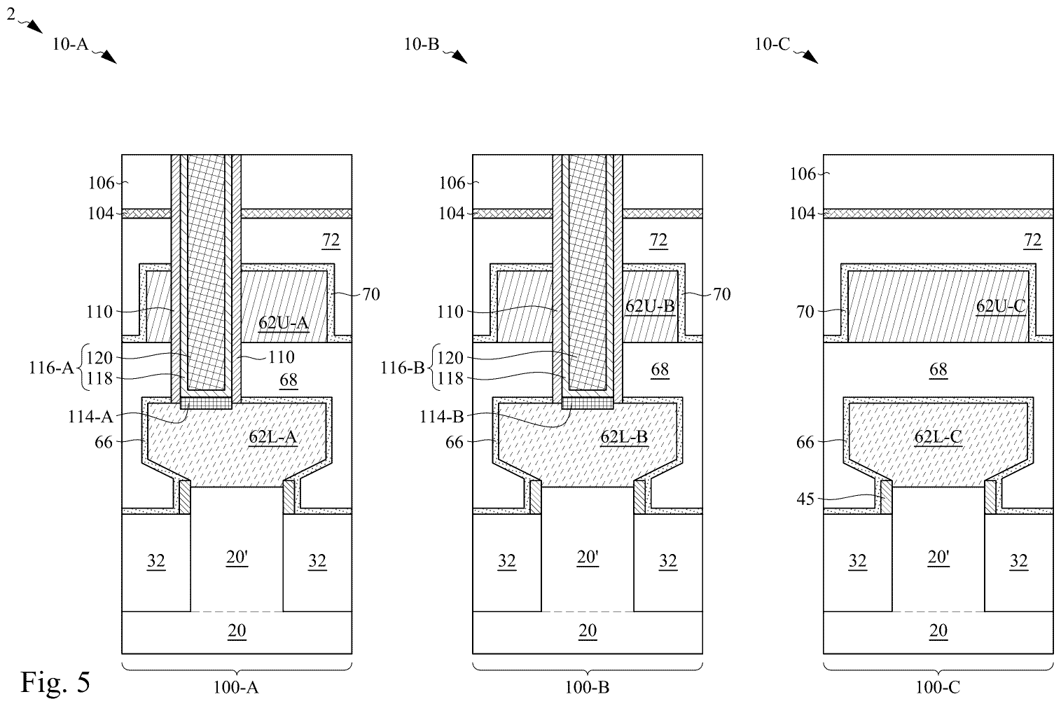

The material of dielectric contact spacers 110 may comprise silicon oxide, silicon nitride, silicon oxynitride, silicon oxy carbo-nitride, or the like. Dielectric contact spacers 110 may also have a dielectric constant (k value) greater than 3.9, so that it has good isolation ability. The candidate materials may include aluminum oxide, aluminum nitride, hafnium oxide, or the like. The thickness of dielectric contact spacers 110 may be in the range between about 2 nm and about 6 nm, for example. The thickness of dielectric contact spacers 110 is partially determined by Referring to FIG. 5, silicide layers 114-A and 114-B are formed on the top surfaces of lower source/drain regions 62L-A and 62L-B, respectively. The respective process is illustrated as process 212 in the process flow 200 as shown in FIG. 14. The formation process may include depositing a metal layer (not shown), for example, using a conformal deposition process such as Physical Vapor Deposition (PVD). A barrier/capping layer (not shown), which may be a metal nitride layer such as a titanium nitride layer or a tantalum nitride layer, is then deposited over the metal layer. An annealing process is then performed to react the metal layer with the silicon (and germanium, if any) in lower source/drain regions 62L-A and 62L-B. Source/drain silicide layers 114-A and 114-B are thus formed. The annealing process may be performed through Rapid Thermal Anneal (RTA), furnace anneal, or the like.

The barrier layer and the remaining metal layer may then be removed, for example, in an anisotropic etching process. Next, passing-through contact plugs 116-A and 116-B are formed to fill contact opening 108-A and 108-B and to contact silicide layers 114-A and 114-B, respectively. Passing-through contact plugs 116-A and 116-B passes through (hence the name) upper source/drain regions 62U-A and 62U-B, respectively, and are physically isolated from upper source/drain regions 62U-A and 62U-B by dielectric contact spacers 110.

In accordance with some embodiments, passing-through contact plugs 116-A and 116-B are formed of a homogeneous metallic material such as tungsten, cobalt, ruthenium, or the like, or alloys thereof. In accordance with alternative embodiments, the formation of the passing-through contact plugs 116-A and 116-B may include forming a barrier layer 118, which may comprise titanium, titanium nitride, tantalum, tantalum nitride, or the like. Next, a metallic material 120 is deposited over and in contact with the barrier layer. The metallic material 120 may include tungsten, cobalt, copper, nickel, or the like. While not shown, barrier layer 118 and metallic material 120 further include portions over dielectric layer 106. The respective process is illustrated as process 214 in the process flow 200 as shown in FIG. 14. Throughout the description, the interfaces between barrier layer 118 and metallic material 120 in passing-through contact plugs 116-A and 116-B (and in other contact plugs as subsequently discussed) are illustrated as being dashed to indicate that the barrier layers may be, or may not be formed.

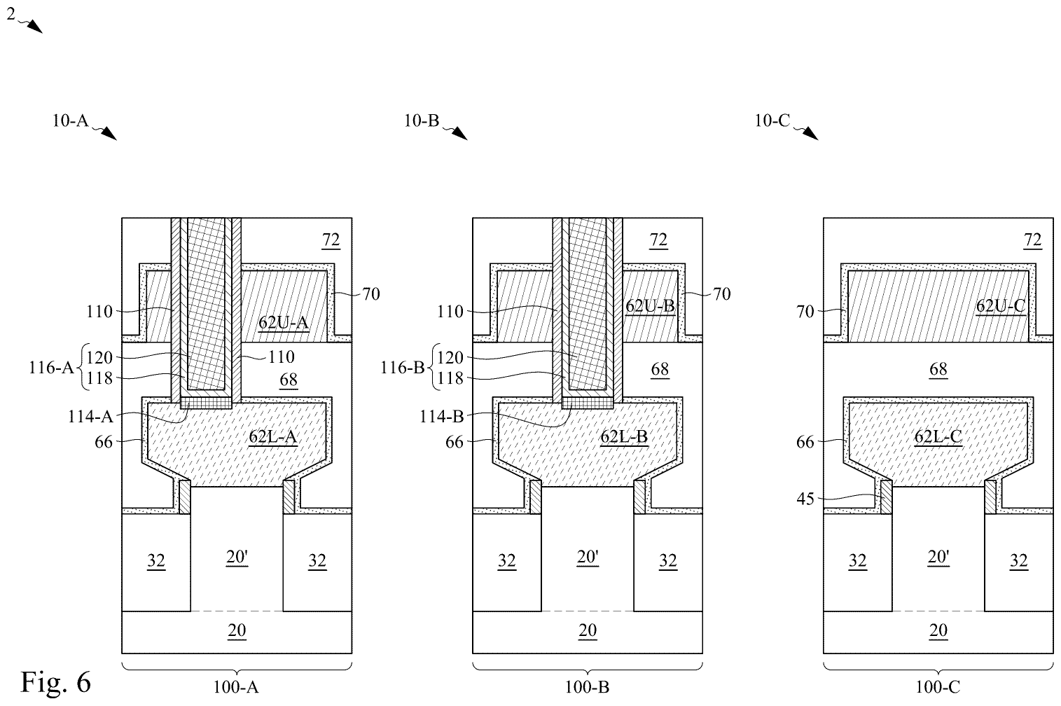

Referring to FIG. 6, a planarization process such as a CMP process or a mechanical grinding process is performed to remove excess portions of the deposited materials, leaving passing-through contact plugs 116-A and 116-B. The respective process is illustrated as process 216 in the process flow 200 as shown in FIG. 14. In accordance with some embodiments, the CMP process is performed using CMP stop layer 104 to stop the process, followed by a light CMP process or an etching process to remove CMP stop layer 104.

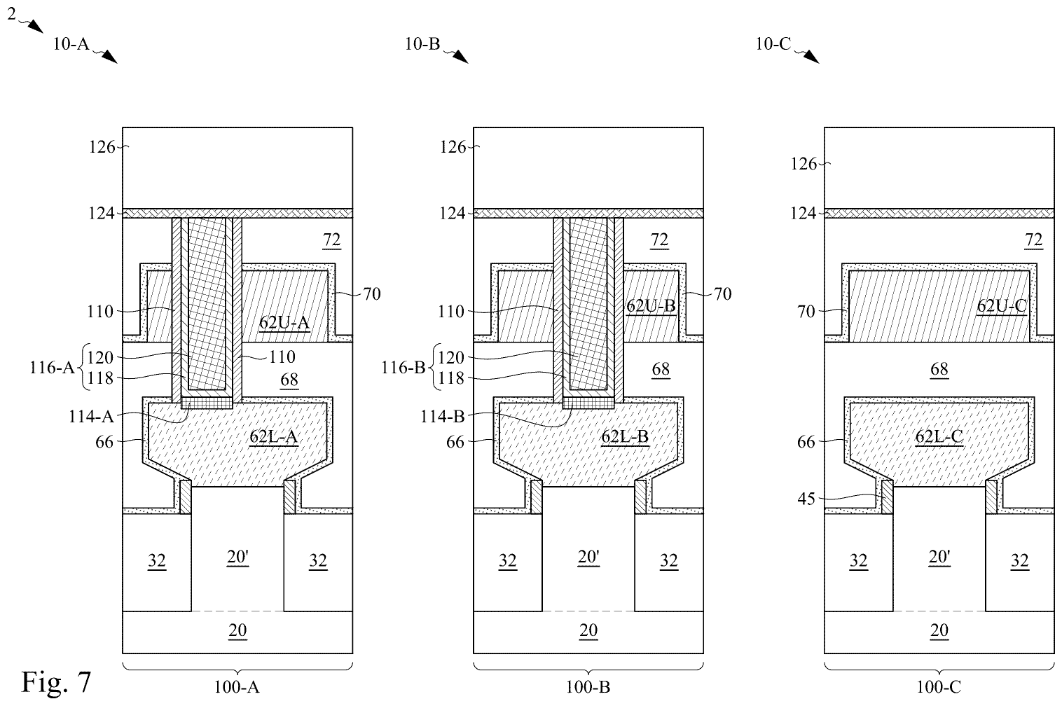

Referring to FIG. 7, etch stop layer 124 and dielectric layer 126 are formed. The respective process is illustrated as process 218 in the process flow 200 as shown in FIG. 14. Etch stop layer 124 may comprise AlN, AlO, SiOC, or the like, or multilayers thereof. Dielectric layer 126 may comprise silicon oxide, silicon nitride, silicon oxynitride, silicon carbide, or the like.

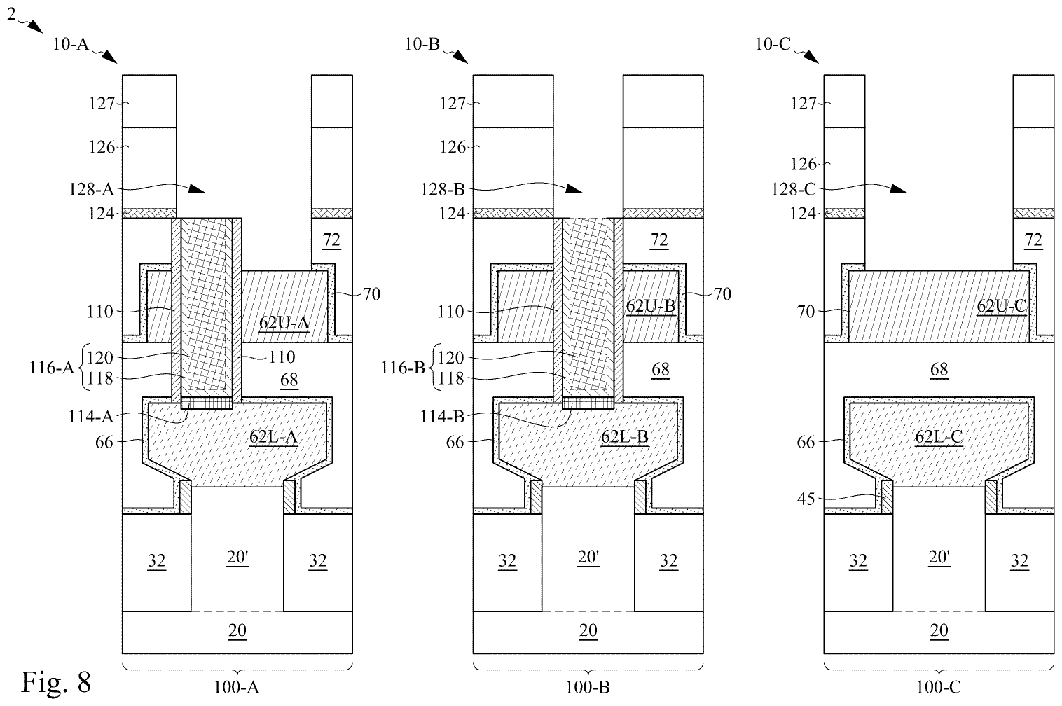

Referring to FIG. 8, a patterned etching mask 127, which may comprise, for example, a photoresist, is formed. The respective process is illustrated as process 220 in the process flow 200 as shown in FIG. 14.

An etching process is performed to etch dielectric layer 126, etch stop layer 124, the second ILD 72, and the second CESL 70 in device regions 100-A, 100-B, and 100-C, and to form contact openings 128-A, 128-B, and 128-C, respectively. Contact openings 128-A, 128-B, and 128-C are formed through a same photolithography process using a same photolithography mask (which includes transparent portions allowing light to pass through and opaque portions for blocking light, not shown).

The top surfaces of upper source/drain regions 62U-A and 62U-C are exposed to contact openings 128-A and 128-C, respectively. The respective process is illustrated as process 222 in the process flow 200 as shown in FIG. 14. The etching for forming contact opening 128-B is stopped on the top surface of pass-through contact plug 114-B. The top surface of passing-through contact plug 116-A is exposed to contact opening 128-A. The sidewall of dielectric contact spacer 110 in device region 100-A is also exposed to contact opening 128-A. After the etching process, etching mask 127 is removed.

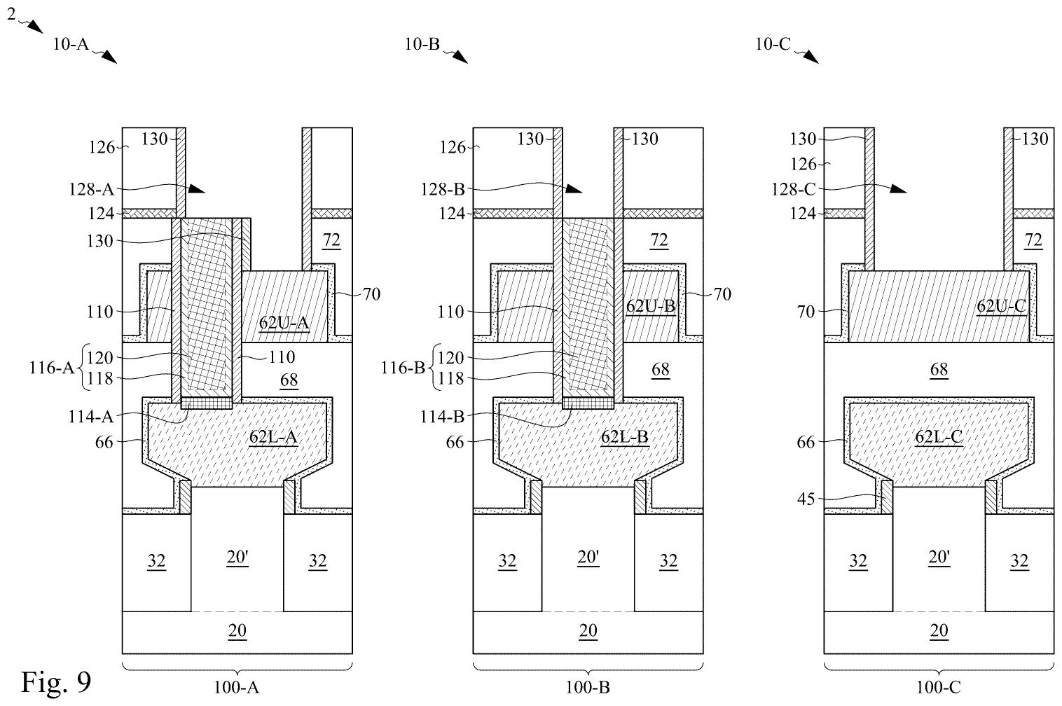

Referring to FIG. 9, dielectric contact spacers 130 are formed in contact openings 128-A, 128B, and 128-C. The respective process is illustrated as process 224 in the process flow 200 as shown in FIG. 14. In accordance with some embodiments, the formation of dielectric contact spacers 130 includes a conformal deposition process such as CVD or ALD to form a conformal dielectric layer, and performing an anisotropic etching process to remove horizontal portions of the conformal dielectric layer. The material of dielectric contact spacers 130 may be selected from the same group of candidate materials for forming dielectric contact spacers 110, and may be the same as or different from the material of dielectric spacer layers 110.

In contact opening 128-A, the dielectric contact spacer 130 includes a portion contacting the dielectric contact spacer 110, and other portions contacting dielectric layer 126, etch stop layer 124, the second ILD 72, and the second CESL 70. Dielectric contact spacers 130 may form rings encircling contact openings 128-A and 128-B when viewed from the top of wafer 2. In the contact opening 128-A, the portion of dielectric contact spacer 130 in contact with dielectric contact spacer 110 may have a smaller height than the portion of dielectric contact spacer 130 in contact with the dielectric layer 126, etch stop layer 124, the second ILD 72, and the second CESL 70.

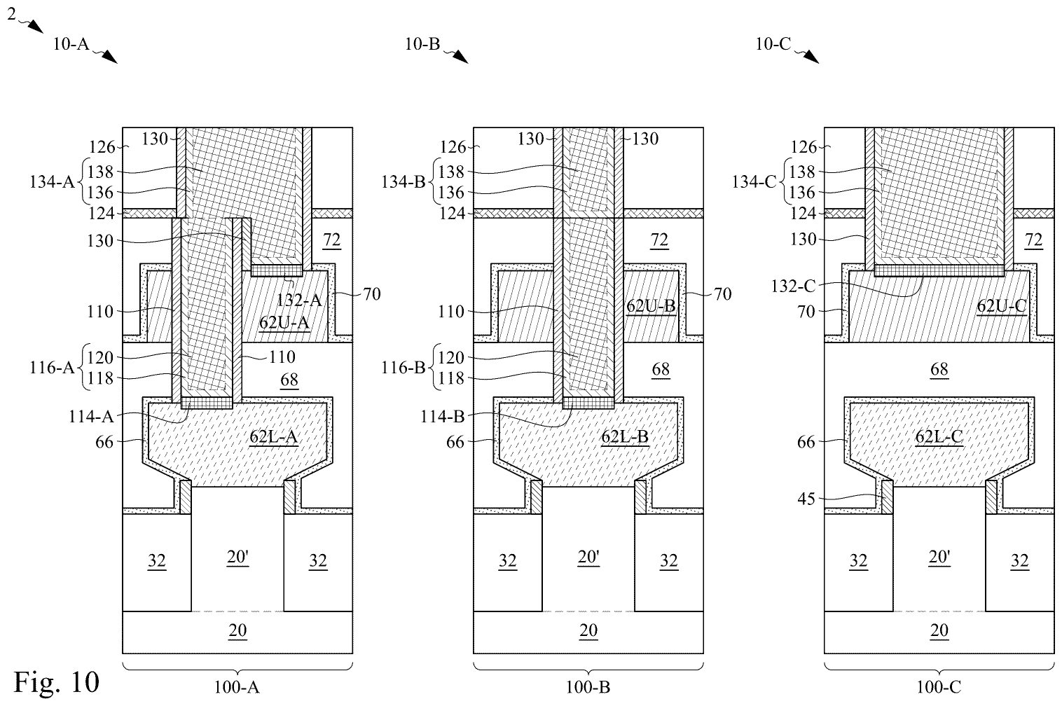

Referring to FIG. 10, silicide layers 132-A and 132-C are formed on the top surfaces of upper source/drain regions 62U-A and 62U-C, respectively. The respective process is illustrated as process 226 in the process flow 200 as shown in FIG. 14. The materials and the formation processes of silicide layers 132-A and 132-C may be essentially the same as that of silicide layers 114-A and 114-B, and thus are not repeated.

Further referring to FIG. 10, upper source/drain contact plugs 134-A, 134-B, and 134-C are formed to fill contact openings 128-A, 128B, and 108-C, respectively, and to contact silicide layer 132-A, passing-through contact plug 116-B, and silicide layer 132-C, respectively. The respective process is illustrated as process 228 in the process flow 200 as shown in FIG. 14.

In accordance with some embodiments, the entireties of source/drain contact plugs 134-A, 134-B, and 134-C are formed of a homogeneous metallic material such as tungsten, cobalt, ruthenium, or the like, or alloys thereof. In accordance with alternative embodiments, the formation process may include forming a barrier layer 136, which may comprise titanium, titanium nitride, tantalum, tantalum nitride, or the like. Next, a metallic material 138 is deposited over and in contact with the barrier layer 136. The metallic material 138 may include tungsten, cobalt, copper, nickel, or the like. Dashed interfaces are shown between barrier layer 136 and metallic material 138 to indicate that source/drain contact plugs 134-A, 134-B, and 134-C may be formed of a homogenous material, or may have a multi-layer structure.

A planarization process such as a CMP process or a mechanical grinding process is then performed to remove excess portions of the deposited material(s), leaving upper source/drain contact plugs 134-A, 134-B, and 134-C.

Upper source/drain contact plug 134-A electrically connects upper source/drain region 62U-A with the passing-through contact plugs 116-A and lower source/drain region 62L-A. Upper source/drain contact plug 134-B is electrically connected to passing-through contact plugs 116-B and lower source/drain region 62L-B, and is electrically decoupled from upper source/drain region 62U-B at this stage. Upper source/drain contact plug 134-B may be, or may not be, electrically connected to passing-through contact plugs 116-B through the subsequently formed overlying contact plugs and/or metal lines. Upper source/drain contact plug 134-C is electrically connected to upper source/drain regions 62U-C, and is electrically decoupled from lower source/drain region 62L-C.

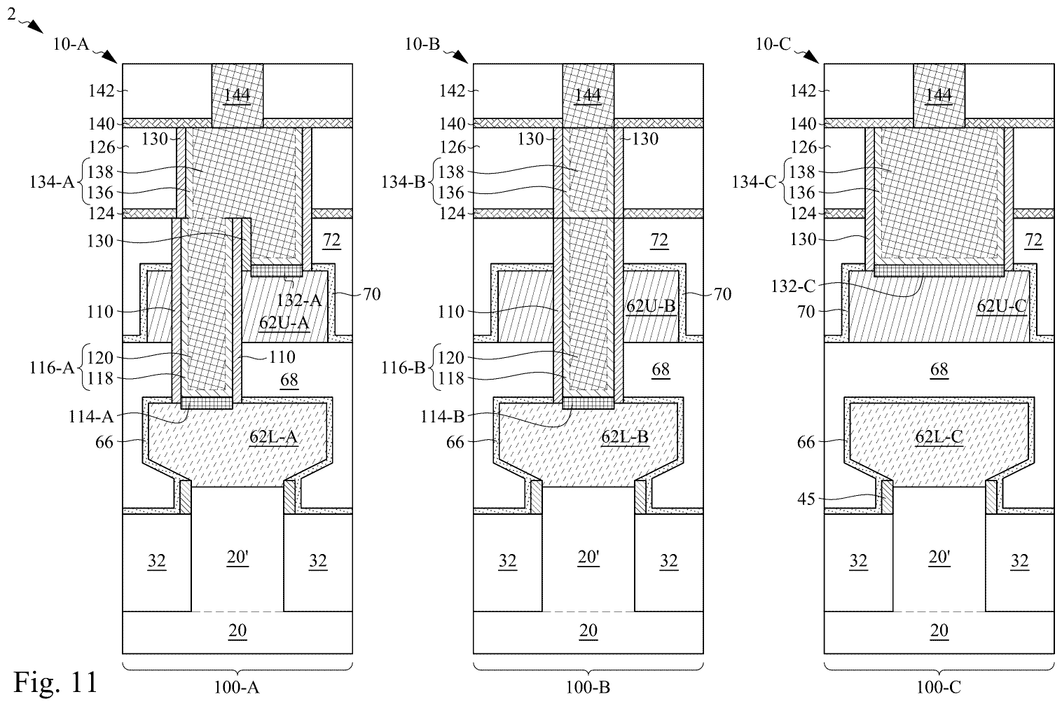

Referring to FIG. 11, etch stop layer 140 and dielectric layer 142 are formed. The respective process is illustrated as process 230 in the process flow 200 as shown in FIG. 14. Etch stop layer 140 may comprise AlN, AlO, SiOC, or the like, or multilayers thereof. Dielectric layer 142 may comprise silicon oxide, silicon nitride, silicon oxynitride, silicon carbide, or the like.

Conductive features 144 such as metal lines or metal vias may then be formed over and electrically coupled to upper source/drain contact plugs 134-A, 134-B, and 134-C. The respective process is illustrated as process 232 in the process flow 200 as shown in FIG. 14. Conductive features 144 may comprise tungsten, cobalt, titanium, titanium nitride, tantalum, tantalum nitride, copper, aluminum, or the like, alloys thereof, and/or multilayers thereof.

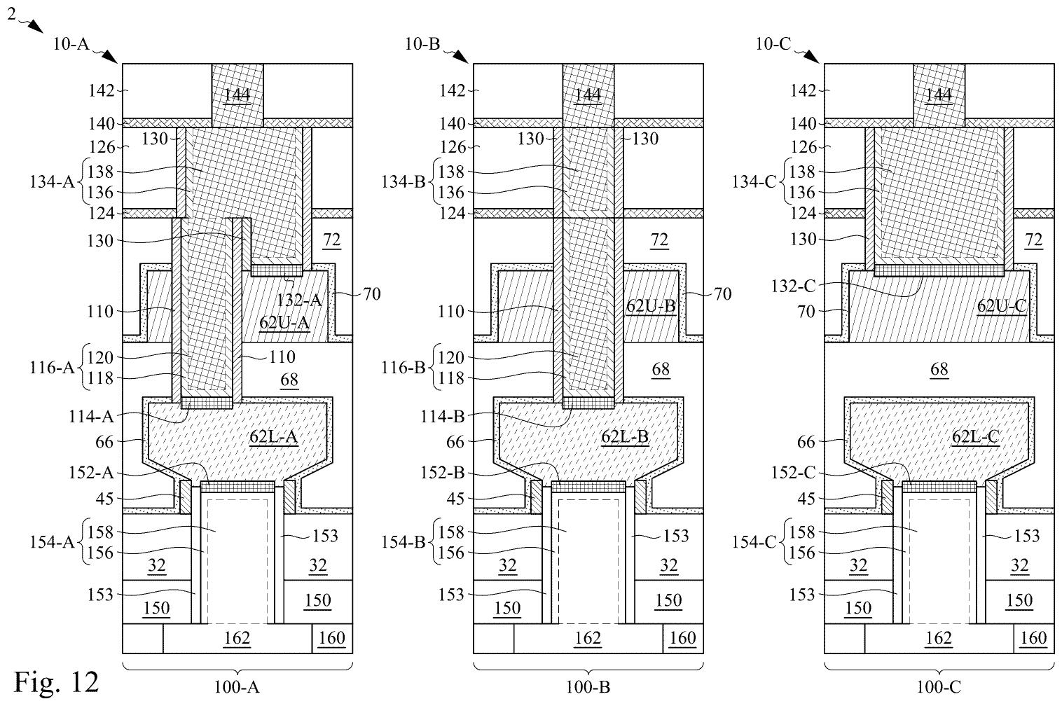

In accordance with alternative embodiments, there may not be conductive feature 144 formed over and contacting upper source/drain contact plug 134-A. Accordingly, upper source/drain contact plug 134-A may not be connected to any overlying conductive feature, and the entirety of the top surface of upper source/drain contact plug 134-A is in contact with etch stop layer 140. Accordingly, upper source/drain contact plug 134-A is connected to the backside features (as shown in FIG. 12), and is not connected to any overlying conductive features.

FIG. 12 illustrates the formation of backside source/drain contact plugs electrically connected to lower source/drain regions, and the formation of backside redistribution lines in accordance with some embodiments. The respective process is illustrated as process 234 in the process flow 200 as shown in FIG. 14. In accordance with some embodiments, substrate 20 (FIG. 11) is removed, for example, through a CMP process and/or an etching process(es). A dielectric substrate 150 (FIG. 12) may be formed.

Semiconductor strips 20′ are etched to form openings, through which the bottoms of lower source/drain regions 62L-A, 62L-B, and 62L-C are exposed. Silicide layers 152-A, 152-B, and 152-C are formed underlying and contacting the bottom surfaces of lower source/drain regions 62L-A, 62L-B, and 62L-C, respectively. The materials and the formation processes of silicide layers 152-A, 152-B, and 152-C may be essentially the same as that of silicide layers 114-A and 114-B, and are not repeated herein.

Further referring to FIG. 12, backside contact spacers 153 are formed, which may be formed using the same method for forming dielectric contact spacers 130. The material of the backside contact spacers 153 may be selected from the same group of candidate materials of dielectric contact spacers 130.

Lower source/drain contact plugs 154-A, 154-B, and 154-C are formed to fill the remaining contact openings, and encircled by backside contact spacers 153. Lower source/drain contact plugs 154-A, 154-B, and 154-C are in contact with silicide layers 152-A, 152-B, and 152-C, respectively. In accordance with some embodiments, lower source/drain contact plugs 154-A, 154-B, and 154-C is formed of a homogeneous metallic material such as tungsten, cobalt, ruthenium, or the like, or an alloy thereof. In accordance with alternative embodiments, lower source/drain contact plugs 154-A, 154-B, and 154-C may have a multi-layer structure, with the structure and materials essentially the same as that of contact plugs 134-A.

A planarization process such as a CMP process or a mechanical grinding process is then performed to remove excess portions of the deposited material(s), leaving lower source/drain contact plugs 154-A, 154-B, and 154-C.

Backside redistribution lines 162 are formed on the backside of CFETs, and are formed in dielectric layer 160. Backside redistribution lines 162 are thus electrically connected to passing-through contact plugs 116-A and 116-B, and to lower source/drain region 62L-C.

In accordance with some embodiments, backside redistribution lines 162 may be power nodes, and powers such as VDD and/or VSS may be conducted from the backside of CFETs 10 to their front side, or conducted from the front side of CFETs 10 to their backside. Accordingly, lower source/drain regions 62L-A and 62L-B are formed as the interconnection structure for conducting the power. Advantageously, the power conduction from the backside to front side (or in reversed direction) does not occupy additional chip area.

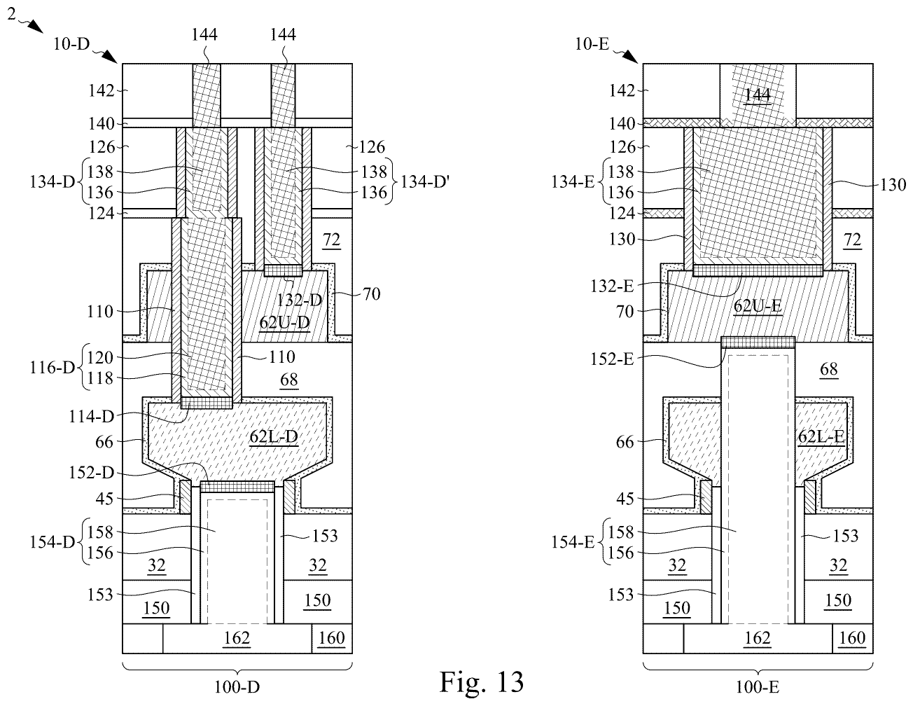

FIG. 13 illustrates the CFET 10-D in device region 100-D and the CFET 10-E in device region 100-E, which may be formed in the same wafer and the same device die as CFETs 10-A, 10-B, and 10-C. The formation processes of CFET 10-D and the corresponding passing-through contact plugs 116-D and 116-E, the upper source/drain contact plugs 134-D, 134-D′ and 134-E, and the backside source/drain contact plugs 154-D and 154-E may share the same processes as the corresponding contact plugs in CFETs 10-A, 10-B, and 10C. The lower source/drain regions 62L-D and 62L-E and upper source/drain regions 62U-D and 62U-E are also illustrated.

In device region 100-D, upper source/drain contact plug 134-D and 134-D′ are formed, and are overlying and joining passing-through contact plug 116-D and silicide layer 132-D, respectively. Upper source/drain contact plug 134-D′ is physically spaced apart from passing-through contact plug 114-D, and may be electrically disconnected from passing-through contact plug 114-D, or electrically connected to the passing-through contact plug 114-D through upper metal lines and/or vias (including conductive features 44).

In device region 100-E, silicide layer 134-E is formed, and is overlying silicide layer 132-E. Backside source/drain contact plug 154-E is formed from the backside of wafer 2 as a passing-through contact plug that passes through lower source/drain region 62L-E. Backside source/drain contact plug 154-E is physically separated from, and may be electrically decoupled from, lower source/drain region 62L-E. Alternatively, backside source/drain contact plug 154-E may be electrically connected to lower source/drain region 62L-E through additional backside conductive features, which are not shown. Through passing-through contact plug 154-E and upper source/drain region 62U-E, power may be conducted from front side to backside (or from backside to the front side) of CFETs. For example, the illustrated conductive features 162 may be power nodes, which may be VDD or VSS.

The embodiments of the present disclosure have some advantageous features. A passing-through contact plug may be formed to penetrate through one of the upper source/drain region and the lower source/drain region in a CFET, and is electrically connected to the other one of the upper source/drain region and the lower source/drain region. Power (or electrical signals) may be conducted from front side to the backside (or from the backside to the front side) of the CFET through a corresponding source/drain region. Accordingly, the passing-through contact plug occupies the same chip area as the source/drain region, and no extra chip area is needed.

If, however, deep power contact plugs (instead of passing-through contact plugs) are formed, the deep power contact plugs will be aside of the CFETs and thus will occupy extra chip areas. In addition, the deep power contact plugs will extend from the top surface of the second ILD to the bottom of the STI regions, and thus will have a high aspect ratio. The deep power contact plugs thus will suffer from the problems related to the high aspect ratio.

In accordance with some embodiments of the present disclosure, a method comprises forming a complementary field-effect transistor comprising forming a lower source/drain region; and forming an upper source/drain region over the lower source/drain region; performing an etching process to etch-through the upper source/drain region and to form a first contact opening, wherein the etching process is stopped on a top surface of the lower source/drain region; forming a first dielectric contact spacer in the first contact opening; forming a first silicide layer over the lower source/drain region; forming a first contact plug over and contacting the first silicide layer; and forming a second silicide layer underlying and contacting a bottom surface of the lower source/drain region.

In an embodiment, the method further comprises forming a second contact plug underlying and joined to the second silicide layer. In an embodiment, the method further comprises forming a bottom conductive feature underlying and electrically connected to the second contact plug. In an embodiment, the bottom conductive feature is connected to a power node. In an embodiment, the method further comprises forming a third silicide layer over and contacting the upper source/drain region; and forming a second contact plug over and electrically connecting the first contact plug to the third silicide layer.

In an embodiment, the first contact plug is in physical contact with the second contact plug. In an embodiment, the method further comprises forming an etch stop layer over the first contact plug; forming a dielectric layer over the etch stop layer; and etching the dielectric layer and the etch stop layer to form a second contact opening, wherein a first top surface of the upper source/drain region is exposed to the second contact opening, and wherein the second contact plug is formed in the second contact opening.

In an embodiment, the method further comprises forming a second dielectric contact spacer in the second contact opening, wherein the second contact plug is encircled by the second dielectric contact spacer. In an embodiment, the method further comprises, in a same process for forming the second contact plug, forming a third contact plug, wherein the third contact plug is in contact with an additional silicide layer, and the additional silicide layer is over and contacting the upper source/drain region. In an embodiment, the method further comprises forming a second contact plug over and physical contacting the first contact plug.

In accordance with some embodiments of the present disclosure, a method comprises forming a lower source/drain region; forming a first contact etch stop layer over the lower source/drain region; forming a first inter-layer dielectric over the first contact etch stop layer; forming an upper source/drain region over the first inter-layer dielectric; forming a second contact etch stop layer over the upper source/drain region; forming a second inter-layer dielectric over the second contact etch stop layer; performing a first etching process to form a first contact opening, wherein the first contact opening penetrates through the upper source/drain region to reach the lower source/drain region; forming a first dielectric contact spacer in the first contact opening; forming a first contact plug in the first contact opening; and forming a second contact plug underlying and electrically connected to the lower source/drain region, wherein the second contact plug is electrically connected to the first contact plug through the lower source/drain region.

In an embodiment, the method further comprises forming a second dielectric contact spacer, wherein the second contact plug is encircled by the second dielectric contact spacer. In an embodiment, the method further comprises forming an etch stop layer over the first contact plug; forming a dielectric layer over the etch stop layer; etching the dielectric layer and the etch stop layer to form a second contact opening, wherein a first top surface of the first contact plug is exposed; and forming a third contact plug over and contacting the first contact plug.

In an embodiment, the method further comprises forming a silicide layer over and contacting the upper source/drain region, wherein the third contact plug is further over and contacting the silicide layer. In an embodiment, the method further comprises forming a second contact spacer in the second contact opening, wherein the third contact plug is encircled by the second contact spacer. In an embodiment, in a cross-section of the second contact spacer, the second contact spacer comprises a first portion and a second portion on opposing sides of a lower part of the second contact plug, wherein the first portion is shorter than the second portion.

In accordance with some embodiments of the present disclosure, a structure comprises a first transistor comprising a lower source/drain region of a first conductivity type; a second transistor comprising an upper source/drain region overlapping and spaced apart from the lower source/drain region, wherein the upper source/drain region is of a second conductivity type opposing the first conductivity type; a first contact plug over a first source/drain region of the lower source/drain region and the upper source/drain region; and a second contact plug under the first source/drain region of the of the lower source/drain region and the upper source/drain region, wherein the first contact plug is electrically connected to the second contact plug through the first source/drain region. In an embodiment, the first source/drain region of the lower source/drain region and the upper source/drain region is the lower source/drain region, and wherein the first contact plug penetrates through the upper source/drain region.

In an embodiment, the first source/drain region of the lower source/drain region and the upper source/drain region is the upper source/drain region, and wherein the second contact plug penetrates through the lower source/drain region. In an embodiment, the structure further comprises a dielectric contact spacer encircling the first contact plug, wherein the dielectric contact spacer physically separates the first contact plug from the first source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a complementary field-effect transistor comprising:
forming a lower source/drain region; and
forming an upper source/drain region over the lower source/drain region;
performing an etching process to etch-through the upper source/drain region and to form a first contact opening, wherein the etching process is stopped on a top surface of the lower source/drain region;
forming a first dielectric contact spacer in the first contact opening;
forming a first silicide layer over the lower source/drain region;
forming a first contact plug over and contacting the first silicide layer; and
forming a second silicide layer underlying and contacting a bottom surface of the lower source/drain region.

2. The method of claim 1 further comprising forming a second contact plug underlying and joined to the second silicide layer.

3. The method of claim 2 further comprising forming a bottom conductive feature underlying and electrically connected to the second contact plug.

4. The method of claim 3, wherein the bottom conductive feature is connected to a power node.

5. The method of claim 1 further comprising:
forming a third silicide layer over and contacting the upper source/drain region; and
forming a second contact plug over and electrically connecting the first contact plug to the third silicide layer.

6. The method of claim 5, wherein the first contact plug is in physical contact with the second contact plug.

7. The method of claim 5 further comprising:
forming an etch stop layer over the first contact plug;
forming a dielectric layer over the etch stop layer; and
etching the dielectric layer and the etch stop layer to form a second contact opening, wherein a first top surface of the upper source/drain region is exposed to the second contact opening, and wherein the second contact plug is formed in the second contact opening.

8. The method of claim 7 further comprising forming a second dielectric contact spacer in the second contact opening, wherein the second contact plug is encircled by the second dielectric contact spacer.

9. The method of claim 5 further comprising:
in a same process for forming the second contact plug, forming a third contact plug, wherein the third contact plug is in contact with an additional silicide layer, and the additional silicide layer is over and contacting the upper source/drain region.

10. The method of claim 1 further comprising:
forming a second contact plug over and physical contacting the first contact plug.

11. A method comprising:
forming a lower source/drain region;
forming a first contact etch stop layer over the lower source/drain region;
forming a first inter-layer dielectric over the first contact etch stop layer;
forming an upper source/drain region over the first inter-layer dielectric;
forming a second contact etch stop layer over the upper source/drain region;
forming a second inter-layer dielectric over the second contact etch stop layer;
performing a first etching process to form a first contact opening, wherein the first contact opening penetrates through the upper source/drain region to reach the lower source/drain region;
forming a first dielectric contact spacer in the first contact opening;
forming a first contact plug in the first contact opening; and
forming a second contact plug underlying and electrically connected to the lower source/drain region, wherein the second contact plug is electrically connected to the first contact plug through the lower source/drain region.

12. The method of claim 11 further comprising forming a second dielectric contact spacer, wherein the second contact plug is encircled by the second dielectric contact spacer.

13. The method of claim 11 further comprising:
forming an etch stop layer over the first contact plug;
forming a dielectric layer over the etch stop layer;
etching the dielectric layer and the etch stop layer to form a second contact opening, wherein a first top surface of the first contact plug is exposed; and
forming a third contact plug over and contacting the first contact plug.

14. The method of claim 13 further comprising:
forming a silicide layer over and contacting the upper source/drain region, wherein the third contact plug is further over and contacting the silicide layer.

15. The method of claim 13 further comprising forming a second contact spacer in the second contact opening, wherein the third contact plug is encircled by the second contact spacer.

16. The method of claim 15, wherein in a cross-section of the second contact spacer, the second contact spacer comprises a first portion and a second portion on opposing sides of a lower part of the second contact plug, wherein the first portion is shorter than the second portion.

17. A structure comprising:
a first transistor comprising:
a lower source/drain region of a first conductivity type;
a second transistor comprising:
an upper source/drain region overlapping and spaced apart from the lower source/drain region, wherein the upper source/drain region is of a second conductivity type opposing the first conductivity type;
a first contact plug over a first source/drain region of the lower source/drain region and the upper source/drain region; and
a second contact plug under the first source/drain region of the of the lower source/drain region and the upper source/drain region, wherein the first contact plug is electrically connected to the second contact plug through the first source/drain region.

18. The structure of claim 17, wherein the first source/drain region of the lower source/drain region and the upper source/drain region is the lower source/drain region, and wherein the first contact plug penetrates through the upper source/drain region.

19. The structure of claim 17, wherein the first source/drain region of the lower source/drain region and the upper source/drain region is the upper source/drain region, and wherein the second contact plug penetrates through the lower source/drain region.

20. The structure of claim 17 further comprising a dielectric contact spacer encircling the first contact plug, wherein the dielectric contact spacer physically separates the first contact plug from the first source/drain region.
